(19) United States
(12) Patent Application Publication
(10) Pub. No.: US 2023/0168551 A1
(43) Pub. Date: Jun. 1, 2023

(54) DISPLAY PANEL, MANUFACTURING METHOD THEREOF, AND DISPLAY DEVICE

(71) Applicant: TCL China Star Optoelectronics Technology Co., Ltd., Shenzhen, Guangdong (CN)

(72) Inventors: Litao YANG, Shenzhen, Guangdong (CN); Xing OUYANG, Shenzhen, Guangdong (CN)

(73) Assignee: TCL China Star Optoelectronics Technology Co., Ltd., Shenzhen, Guangdong (CN)

(21) Appl. No.: 17/600,385

(22) PCT Filed: Jul. 15, 2021
(86) PCT No.: PCT/CN2021/106503

§ 371 Date: Sep. 30, 2021

(30) Foreign Application Priority Data
Apr. 28, 2021 (CN) 202110464609.4

(51) Int. Cl. G02F 1/1362; H01L 27/12

(52) U.S. Cl. CPC G02F 1/136263; G02F 1/136222; G02F 1/136295; H01L 27/124

(57) ABSTRACT

A display panel, a manufacturing method thereof, and a display device are provided. The display panel includes a first signal line. The first signal line includes a first section, a second section, a transmitting defect section disposed between the first section and the second section, an interval layer disposed on the first signal line, and a repairing part disposed on the interval layer and respectively connected to the first section and the second section. The repairing part includes a first conductive layer disposed on the interval layer and a second conductive layer disposed on the first conductive layer.

### FIELD

The present disclosure relates to a field of display technologies, and more particularly, to a display panel, a manufacturing method thereof, and a display device having the display panel.

### BACKGROUND

Liquid crystal displays (LCDs) are one of the most widely-used plat display devices, and a liquid crystal panel is a core of the LCDs.

Conventional liquid crystal panels usually include a color filter (CF) substrate, a thin-film transistor (TFT) array substrate, and a liquid crystal layer disposed between the CF substrate and the TFT array substrate. A working principle of the LCDs is: multiple liquid crystal molecules are disposed between two glass substrates parallel to each other, and a plurality of vertical and horizontal small wires are disposed between the two glass substrates. The wires are electrified to control orientation of the liquid crystal molecules, thereby allowing light emitted from a backlight module to be deflected to generate an image. Wherein, a TFT array is disposed on the TFT array substrate and is configured to drive the liquid crystal molecules to rotate, thereby controlling each pixel to display. A CF layer is disposed on the CF substrate and is configured to form color of each pixel. The CF layer comprises a plurality of red color resists, a plurality of green color resists, and a plurality of blue color resists which are alternately arranged.

A broken line of TFT array substrates is due to defects generated during manufacturing processes of the TFT array substrate, which causes a breakpoint of a signal line in LCD panels and results in display abnormality. Currently, a broken-line detecting process is performed on LCD devices after TFT array substrates are manufactured, thereby repairing a detected broken line. Commonly, a repairing way is to connect a metal long-film between two sides of a breakpoint on a signal line, thereby allowing the signal line to transmit a signal normally. The metal long-film is usually welded to the signal line by a laser fuse process. However, space for welding is small, and a gap is generated between two sides of a breakpoint because a signal line is bumpy, resulting in breakage or large resistance. Consequently, a success rate of repairing is affected.

### SUMMARY

Embodiments of the present disclosure provide a display panel, a manufacturing method thereof, and a display device to solve a following technical issue: in conventional technologies, problems of uneven thickness and breakage are prone to occur on a metal long-film, affecting a success rate of repairing a first signal line.

To solve the above technical problem, an embodiment of the present disclosure provides a display panel, comprising:
a plurality of signal lines, wherein the signal lines comprise at least one first signal line, the at least one first signal line comprises a first section, a second section, and a transmitting defect section between the first section and the second section;
an interval layer disposed on the at least one first signal line; and
a repairing part continuously disposed on the interval layer and connected to the first section and the second section, respectively, wherein the repairing part comprises a first conductive layer disposed on the interval layer and a second conductive layer disposed on the first conductive layer.

In some embodiments of the present disclosure, a recess is formed on a side of the first conductive layer toward the second conductive layer, and the second conductive layer is at least filled in the recess.

In some embodiments of the present disclosure, the second conductive layer is disposed on the interval layer and the first conductive layer, and the second conductive layer covers at least part of the first conductive layer.

In some embodiments of the present disclosure, fluidity of a material of the second conductive layer is greater than fluidity of a material of the first conductive layer.

In some embodiments of the present disclosure, a material of the first conductive layer comprises tungsten, and a material of the second conductive layer comprises silver.

In some embodiments of the present disclosure, the display panel further comprising a color resist layer disposed on the interval layer, wherein the color resist layer comprises a plurality of hollow parts, the repairing part is defined in the hollow parts, and two ends of the repairing part are respectively connected to the first section and the second section by a plurality of openings of the interval layer.

In some embodiments of the present disclosure, the first conductive layer comprises a first connecting section disposed in the openings, the second conductive layer comprises a second connecting section disposed in the openings, and the second connecting section attachedly covers the first connecting section.

In some embodiments of the present disclosure, a shape of the repairing part comprises a straight line, a polyline, or a curved line.

To achieve the above goal, the present disclosure provides a method of manufacturing a display panel, comprising following steps:
forming a plurality of signal lines, wherein the signal lines comprise at least one first signal line, the first signal line comprises a first section, a second section, and a transmitting defect section between the first section and the second section;
forming an interval layer on the signal lines; and
continuously forming a repairing part on the interval layer, wherein the repairing part is connected to the first section and the second section, respectively, and the repairing part comprises a first conductive layer formed on the interval layer and a second conductive layer formed on the first conductive layer.

To achieve the above goal, the present disclosure provides a display device, comprising a display panel, wherein the display panel comprises:
a plurality of signal lines, wherein the signal lines comprise at least one first signal line, the at least one first signal line comprises a first section, a second section, and a transmitting defect section between the first section and the second section;
an interval layer disposed on the at least one first signal line; and
a repairing part continuously disposed on the interval layer and connected to the first section and the second section, respectively, wherein the repairing part comprises a first conductive layer disposed on the interval layer and a second conductive layer disposed on the first conductive layer.

In some embodiments of the present disclosure, a recess is formed on a side of the first conductive layer toward the second conductive layer, and the second conductive layer is at least filled in the recess.

In some embodiments of the present disclosure, the second conductive layer is disposed on the interval layer and the first conductive layer, and the second conductive layer covers at least part of the first conductive layer.

In some embodiments of the present disclosure, fluidity of a material of the second conductive layer is greater than fluidity of a material of the first conductive layer.

In some embodiments of the present disclosure, a material of the first conductive layer comprises tungsten, and a material of the second conductive layer comprises silver.

In some embodiments of the present disclosure, the display panel further comprises a color resist layer disposed on the interval layer, the color resist layer comprises a plurality of hollow parts, the repairing part is defined in the hollow parts, and two ends of the repairing part are respectively connected to the first section and the second section by a plurality of openings of the interval layer.

In some embodiments of the present disclosure, the first conductive layer comprises a first connecting section disposed in the openings, the second conductive layer comprises a second connecting section disposed in the openings, and the second connecting section attachedly covers the first connecting section.

In some embodiments of the present disclosure, a shape of the repairing part comprises a straight line, a polyline, or a curved line.

Regarding the beneficial effects: compared with conventional technologies, in the present disclosure, a repairing part having a first conductive layer and a second conductive layer is connected to a first signal line, and a second conductive layer is disposed on the first conductive layer and overlaps with the first conductive layer. Therefore, a possibility of breakage occurring on the repairing part is reduced, thereby increasing thickness uniformity of the repairing part. As such, a success rate for repairing transmitting defects of the first signal line by the repairing part is effectively increased. Thus, a yield rate of display panels is increased, and a display effect is improved.

### DESCRIPTION OF DRAWINGS

Technical solutions and beneficial effects of the present disclosure are illustrated below in detail in conjunction with drawings and specific embodiments.

FIG. 1 is a structural schematic view showing a conventional long-film repairing structure.

FIG. 2 is a structural schematic view showing a display panel according to an embodiment of the present disclosure.

FIG. 3 is a plan structural schematic view showing the display panel according to the embodiment of the present disclosure.

FIG. 4 is a structural schematic view showing a repairing part according to an embodiment of the present disclosure.

FIG. 5 is a structural schematic view showing another repairing part according to an embodiment of the present disclosure.

FIG. 6 is a structural schematic view showing another display panel according to an embodiment of the present disclosure.

FIG. 7 is a plan structural schematic view showing another display panel according to an embodiment of the present disclosure.

FIG. 8 is a plan structural schematic view showing yet another display panel according to an embodiment of the present disclosure.

FIG. 9 is a structural schematic view showing yet another display panel according to an embodiment of the present disclosure.

FIG. 10 is a plan structural schematic view showing yet another display panel according to the embodiment of the present disclosure.

FIG. 11 is a flowchart showing a method of manufacturing a display panel according to an embodiment of the present disclosure.

### DETAILED DESCRIPTION

Hereinafter a preferred embodiment of the present disclosure will be described with reference to the accompanying drawings to exemplify the embodiments of the present disclosure can be implemented, which can fully describe the technical contents of the present disclosure to make the technical content of the present disclosure clearer and easy to understand. However, the described embodiments are only some of the embodiments of the present disclosure, but not all of the embodiments. All other embodiments obtained by those skilled in the art based on the embodiments of the present disclosure without creative efforts are within the scope of the present disclosure.

In the description of the present disclosure, it should be noted that unless there are express rules and limitations, the terms such as “mount,” “connect,” and “bond” should be comprehended in broad sense. For example, it can mean a permanent connection, a detachable connection, or an integrated connection; it can mean a mechanical connection, an electrical connection, or can communicate with each other; it can mean a direct connection, an indirect connection by an intermediate, or an inner communication or an interreaction between two elements. A person skilled in the art should understand the specific meanings in the present disclosure according to specific situations.

In the description of the present disclosure, unless specified or limited otherwise, it should be noted that, a structure in which a first feature is “on” or “beneath” a second feature may include an embodiment in which the first feature directly contacts the second feature and may also include an embodiment in which an additional feature is formed between the first feature and the second feature so that the first feature does not directly contact the second feature. Furthermore, a first feature “on,” “above,” or “on top of” a second feature may include an embodiment in which the first feature is right “on,” “above,” or “on top of” the second feature and may also include an embodiment in which the first feature is not right “on,” “above,” or “on top of” the second feature, or just means that the first feature has a sea level elevation greater than the sea level elevation of the second feature. While first feature “beneath,” “below,” or “on bottom of” a second feature may include an embodiment in which the first feature is right “beneath,” “below,” or “on bottom of” the second feature and may also include an embodiment in which the first feature is not right “beneath,” “below,” or “on bottom of” the second feature, or just means that the first feature has a sea level elevation less than the sea level elevation of the second feature.

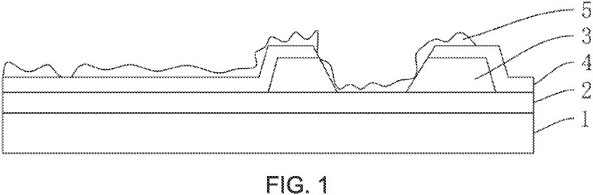

Please refer to FIG. 1, a display panel includes a substrate 1, a passivation layer 2 disposed on the substrate 1, a signal line 3 disposed on the passivation layer 2, and an insulating layer 4 covering the signal line 3. The signal line 3 is configured to transmit signals having a driving function and a display function. In manufacturing processes of the display panel, the signal line 3 is prone to be broken. Currently, a long-film repairing technology is commonly used to repair the signal line 3. Specifically, a metal long-film 5 is formed on the insulating layer 4, and the metal long-film 5 and the signal line 3 have an overlapping part. A laser fuse process is performed on the overlapping part to form an opening penetrating the insulating layer 4, thereby connecting the metal long-film 5 with the signal line 3, wherein the metal long-film 5 needs to be connected to two sides of a breaking point of the signal line 3. Because the signal line 3 is bumpy and has a gap, space for performing the laser fuse process is small. Consequently, a thickness of the metal long-film 5 is uneven. As such, the metal long-film 5 is prone to be broken and has a relatively large resistance, resulting in low a success rate of repairing, affecting a display effect of the display panel.

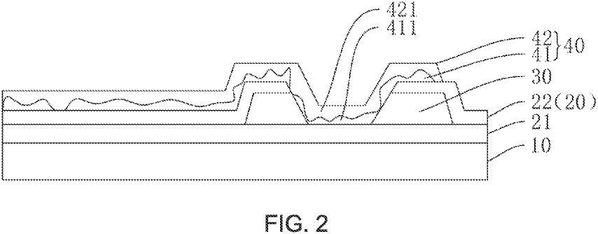

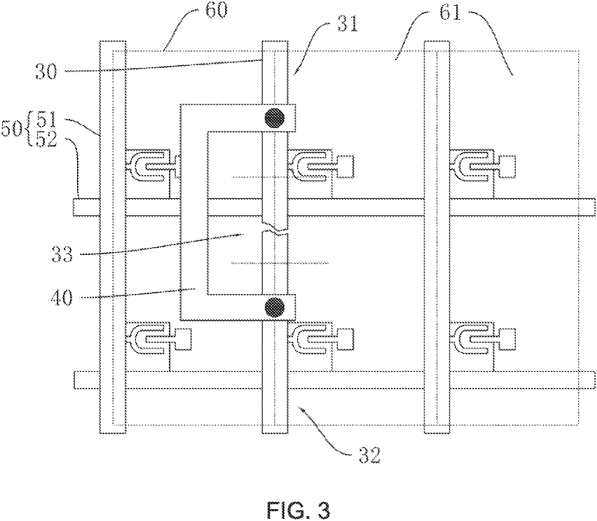

To solve the above technical issues, an embodiment of the present disclosure provides a display panel. As shown in FIG. 2 and FIG. 3, the display panel includes a plurality of signal lines, an interval layer 20, and a repairing part 40.

Wherein, the signal lines include at least one first signal line 30. The first signal line 30 includes a first section 31, a second section 32, and a transmitting defect section between the first section 31 and the second section 32.

The interval layer 20 is disposed on the first signal line 30, the repairing 40 is continuously disposed on the interval layer 20, and the repairing part 40 is connected to the first section 31 and the second section 32, respectively.

The repairing part 40 includes a first conductive layer 41 disposed on the interval layer 20 and a second conductive layer 42 disposed on the first conductive layer 41.

During an actual application, the present embodiment includes the repairing part 40 having the first conductive layer 41 and the second conductive layer 42. Wherein, the second conductive layer 42 is disposed on the first conductive layer 41. When the first conductive layer 41 is not completely repaired, i.e., breakage or uneven thickness occurs, an incompletely repaired part of the first conductive layer 41 can be further repaired by the second conductive layer 42. Therefore, a success rate of repairing a transmitting defect of the first signal line 30 by the repairing part 40 is further increased.

Please refer to FIG. 2 and FIG. 3 again, in the present embodiment, the display panel includes a substrate 10, a gate insulating layer 21 disposed on the substrate 10, an interlayer insulating layer 22 disposed on the gate insulating layer 21, and a color resist layer 60 disposed on the interlayer insulating layer 22.

The display panel includes a plurality of signal lines. The signal lines include at least one first signal line 30 and a plurality of second signal lines 50. During manufacturing processes of the display panel, defects, such as breakage or an overly-large resistance, are prone to occur on the signal lines due to unexpected reasons. Wherein, during the manufacturing processes of the display panel, the first signal line 30 is a signal line that has breakage or an overly-large resistance, and the second signal lines 50 are signal lines which can transmit a signal normally.

Furthermore, the first signal line 30 includes the transmitting defect section 33, and the first section 31 and the second section 32 disposed on two sides of the transmitting defect section 33. Wherein, the transmitting defect section 33 has a signal transmitting defect such as breakage or an overly-large resistance.

The second signal lines 50 may include a plurality of data lines 51 and a plurality of scan lines 52. In the present embodiment, the scan lines 52 is disposed on the substrate 10 and is covered by the gate insulating layer 21. The data lines 51 is disposed on the gate insulating layer 21 and is covered by the interlayer insulating layer 22. Optionally, the second signal lines 50 may also include other driving signal lines such as a power line. In the present embodiment, the second signal lines 50 only including the data lines 51 and the scan lines 52 are taken as an example for description.

It should be noted that the display panel provided by the present embodiment may be a color filter on array (COA) substrate. Specifically, during manufacturing processes of the display panel, a color resist layer is integrally formed on a side of an array substrate. In the present embodiment, the array substrate includes the substrate 10 and a thin-film transistor (TFT) device and an electrode device which are disposed on the substrate. Furthermore, the TFT device includes a gate disposed on a same layer as the scan lines 52 and electrically connected to the scan lines 52, a source and a drain which are disposed on a same layer as the data lines 51 and are electrically connected to the data lines 51, and an active layer. Wherein two sides of the active layer are connected to the source and the drain, respectively, and the color resist layer 60 is disposed on the interlayer insulating layer 22. In addition, the display panel further includes an opposed substrate, a liquid crystal layer disposed between the array substrate and the opposed substrate, a pixel electrode disposed on the array substrate, and a common electrode. The display panel further includes other display components, such as an alignment film and a frame sealant, which are disposed between the array substrate and the opposed substrate. The alignment film and the frame sealant can be disposed according to normal processes and are not described here.

Based on the above description, the data lines 51 and the scan lines 52 cross each other, thereby defining a plurality of pixel areas 61 distributed in an array manner. Wherein, a plurality of color resist blocks are formed on positions on the color resist layer 60 corresponding to the pixel areas 61 and may include red color resist blocks, green color resist blocks, and blue color resist blocks. Each of the pixel areas 61 is provided with the TFT device. Furthermore, the source of the TFT device is electrically connected to the data lines 51, and the gate of the TFT device is electrically connected to the scan lines 52, thereby transmitting a signal.

Optionally, the first signal line 30 may be the data lines 51 or the scan lines 52. When a transmitting defect occur on multiple first signal lines 30 during manufacturing processes, each of the first signal lines 30 are individually selected from one of the data line 51 or the scan line 52, which can be determined according to actual manufacturing processes and is not limited here.

The display panel further includes the repairing part 40 disposed on the interval layer 20 and is connected to the first section 31 and the second section 32 of the first signal line 30, thereby realizing a parallel connection between the repairing part 40 and the transmitting defect section 33. As such, a signal transmitting defect of the first signal line 30 can be repaired.

The repairing part 40 includes the first conductive layer 41 and the second conductive layer 42 which are stacked. By stacking the second conductive layer 42 on the first conductive layer 41, when a repairing defect such as, breakage or an uneven thickness, occurs on the first conductive layer 41, the repairing defect of the first conductive layer 41 may be further repaired by the second conductive layer 42. Therefore, a success rate of repairing the repairing part 40 may be increased.

In the present embodiment, a side of the first conductive layer 41 toward the second conductive layer 42 is provided with a recess, and the second conductive layer 42 is at least filled in the recess. In addition, the second conductive layer 42 includes a flat surface, thereby allowing the repairing part 40 to have a flat surface as well. Therefore, the repair part 40 may have an even thickness and an even resistance, thereby improving a repairing effect.

Furthermore, fluidity of a material of the second conductive layer 42 is greater than fluidity of a material of the first conductive layer 41. It should be noted that the fluidity mentioned here may be fluidity of a material of a layer, which can be liquid or solid, coated on the first conductive layer 41 and the second conductive layer 42. Since the fluidity of the material of the second conductive layer 42 is greater than the fluidity of the material of the first conductive layer 41, the second conductive layer 42 can be better coated on the first conductive layer 41. Therefore, a repairing defect, such as an uneven thickness or breakage, of the first conductive layer 41 can be completely repaired, thereby increasing a success rate of repairing.

Optionally, the material of the first conductive layer 41 includes tungsten, and the material of the second conductive layer 42 includes silver. In the present embodiment, silver can be well coated on a surface of the first conductive layer 41 during manufacturing processes because of fluidity of silver. Therefore, thickness uniformity of the repairing part 40 can be increased.

It should be noted that the color resist layer 60 is provided with a plurality of hollow parts which are continuously formed, and the repairing part 40 is disposed in the hollow parts. Two ends of the repairing part 40 are connected to the first section 31 and the second section 32, respectively, by a plurality of openings penetrating the interval layer 20. The hollow parts are formed by patterning the color resist layer 60. Specifically, part of color resists of the color resist layer 60 is removed to form the hollow parts. Moreover, a pattern of the hollow parts is same as a pattern of the repairing part 40, thereby containing the repairing part 40.

Optionally, a thickness of the repairing part 40 is equal to a thickness of the color resist layer 60, thereby preventing a gap from generating. Therefore, a yield rate of the display panel is increased.

Wherein, the first conductive layer 41 includes a first connecting section 411 disposed in the openings, the second conductive layer 42 includes a second connecting section 421 disposed in the openings, and the second connecting section 421 attachedly covers the first connecting section 411. Furthermore, a side of the second connecting section 421 away from the first connecting section 411 has a flat surface, thereby increasing thickness uniformity of the repairing part 40 in the openings, improving a yield rate of the repairing part 40 connecting with the first signal line 30, and enhancing a repairing effect. Wherein, the second connecting section 421 attachedly covers topography of the first connecting section 411 in the openings. Specifically, because of the fluidity of the material of the second conductive layer 42, the second connecting section 421 can attachedly cover topography of the first connecting section 411. In addition, during manufacturing processes, the second connecting section 421 can attachedly covers topography of the first connecting section 411 by a laser drilling technology. Therefore, the second connecting section 421 can attachedly cover the first connecting section 411 and can attachedly cover topography of layers in the openings.

In the present embodiment, the second conductive layer 42 is disposed on the interval layer 20 and the first conductive layer 41, and covers at least parts of the first conductive layer 41, which specifically includes following situations.

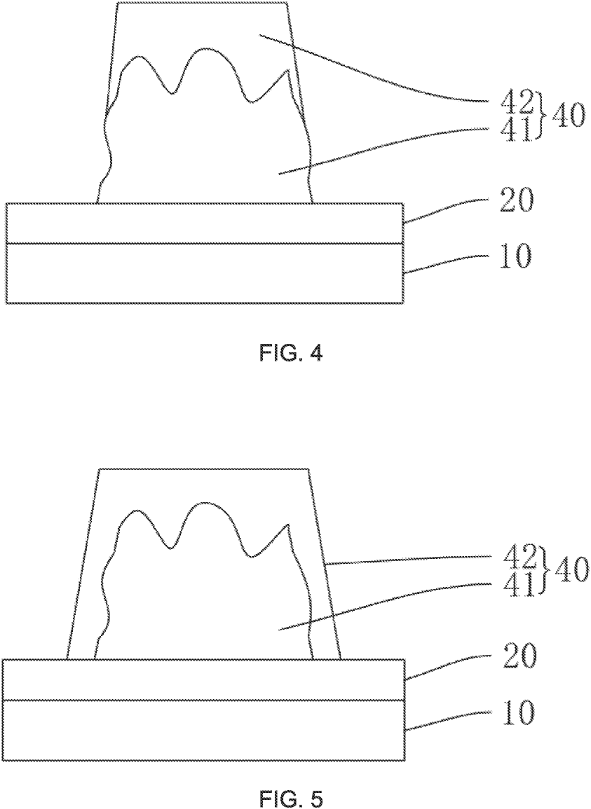

Please refer to FIG. 4, the second conductive layer 42 may cover an upper surface of the first conductive layer 41, thereby allowing the repairing part 40 to have a flat upper surface, which increases a repairing effect.

Please refer to FIG. 5, the second conductive layer 42 may simultaneously cover the upper surface and a lateral surface of the first conductive layer 41, thereby covering the first conductive layer 41 as well as allowing the repairing part 40 to have a flat surface, which further increases a repairing effect.

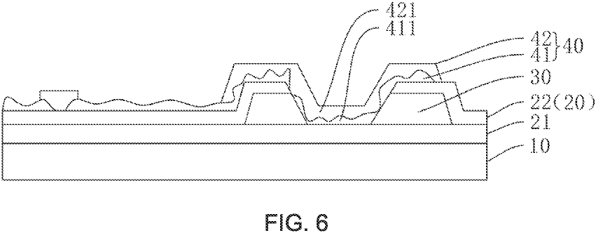

Please refer to FIG. 6, the second conductive layer 42 may also be formed on part of the upper surface of the first conductive layer 41. Specifically, the second conductive layer 42 may be disposed on positions on the first conductive layer 41 having defects and may be disposed on an overlapping part between the first conductive layer 41 and the first signal line 30. Furthermore, positions to be repaired may be positions which are prone to be broken or have an uneven thickness. By disposing the second conductive layer 42 on the positions of the first conductive layer 41 having defects, the defects of the first conductive layer 41 can be repaired. By disposing the second conductive layer 42 on the overlapping part between the first conductive layer and the first signal line 30, a yield rate of the repairing part 40 connecting with the first signal line 30 can be ensured. Therefore, thickness uniformity of the repairing part 40 can be increased, and a success rate of repairing the repairing part 40 can be increased.

It should be noted that the present embodiment is not limited to repair the data lines 51 and the scan lines 52 and can repair other driving signal lines, such as a power line, in the display panel as well. The driving signal lines are not limited here. A success rate of repairing is increased because of the first conductive layer 41 and the second conductive layer 42 which are stacked.

A structure of the display panel provided by the present embodiment is illustrated below in detail in conjunction with specific embodiments.

Please refer to FIG. 2 and FIG. 3, in some embodiments of the present disclosure, the first signal line 30 is the data line 51. Specifically, the display panel includes the substrate 10, the gate insulating layer 21 disposed on the substrate 10, the interlayer insulating layer 22 disposed on the gate insulating layer 22, and the color resist layer 60 disposed on the interlayer insulating layer 22. The plurality of hollow parts are formed in the color resist layer 60. The display panel further includes the repairing part 40 disposed in the hollow parts.

The repairing parts 40 are disposed on the interlayer insulating layer 22. In the present embodiment, the interval layer 20 is the interlayer insulating layer 22, and the repairing part 40 is connected to the first signal line 30 by the openings penetrating the interlayer insulating layer 22.

Furthermore, the first signal line 30 includes the first section 31, the second section 32, and the transmitting defect section 33 disposed between the first section 31 and the second section 32.

The repairing part 40 includes the first conductive layer 41 disposed on the interlayer insulating layer 22 and the second conductive layer 42 disposed on the first conductive layer 41. Wherein, the second conductive layer 42 may only cover part of the upper surface of the first conductive layer 41, or may cover the upper surface and the lateral surface of the first conductive layer 41. Alternatively, the second conductive layer 42 may only be disposed on part of the first conductive layer 41. When repairing a repairing defect, such as an uneven thickness or breakage, occurs on the first conductive layer 41, the repairing defect can be repaired by the second conductive layer 42, thereby increasing a success rate of repairing the repairing part 40.

In the present embodiment, a shape of the repairing part 40 includes a polyline. Correspondingly, the hollow parts formed in the color resist layer 60 are also polylines. Furthermore, the hollow parts may be disposed in any one of the pixel areas 61 which are disposed on two sides of the first signal line 30, which is not limited here.

In summary, in the present embodiment, the repairing part 40 having the first conductive layer 41 and the second conductive layer 42 is connected to the first signal line 30, and the second conductive layer 42 is disposed on the first conductive layer 41 and overlaps with the first conductive layer 41. Therefore, a possibility of breakage occurring on the repairing part 40 is reduced, thickness uniformity of the repairing part 40 is increased, a success rate of repairing the first signal line 30 by the repairing part 40 is effectively increased, a yield rate of the display panel is increased, and a display effect is improved.

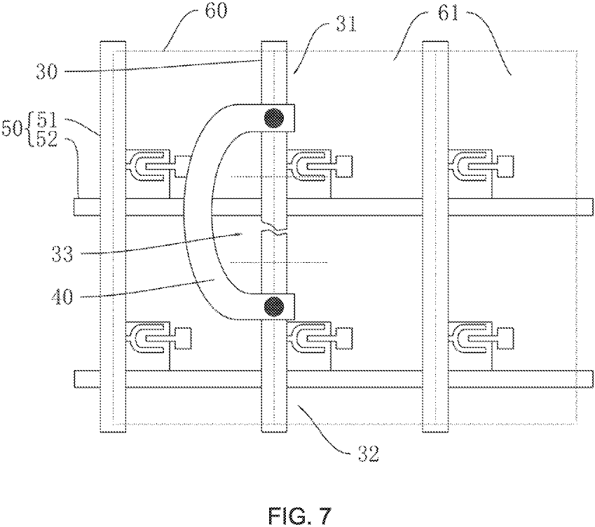

Please refer to FIG. 7, the present disclosure provides another embodiment, a difference between the first embodiment and the present embodiment is: in the present embedment, the shape of the repairing part 40 is a curved line. Furthermore, the repairing part 40 may be disposed on any one of the pixel areas 6 disposed on two sides of the first signal line 30, which is not limited here.

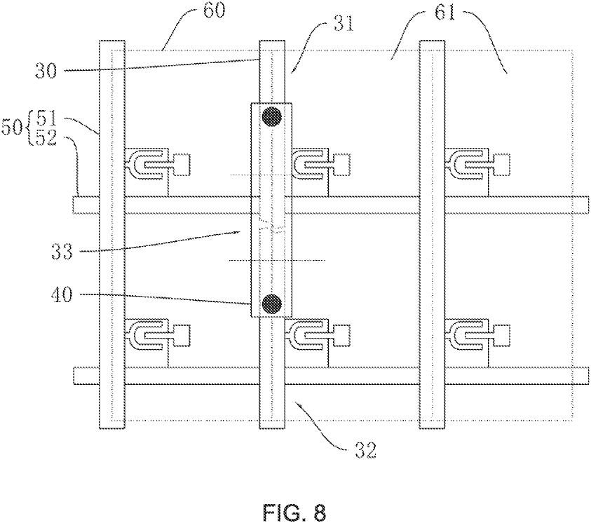

Please refer to FIG. 8, the present disclosure provides yet another embodiment, a difference between the first embodiment of the present embodiment is: in the present embodiment, the repairing part 40 is a straight line. Furthermore, above the first signal line 30, two ends of the repairing part 40 are connected to the first section 31 and the second section 32, respectively, by the openings, thereby repairing a signal transmitting defect of the first signal line 30.

In the present embodiment, the repairing part 40 is disposed on the first signal line 30. Therefore, an area of the pixel areas 61 occupied by the repairing part 40 is reduced, a pixel aperture ratio is increased, and a display effect is improved.

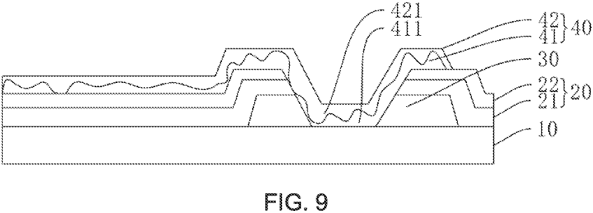

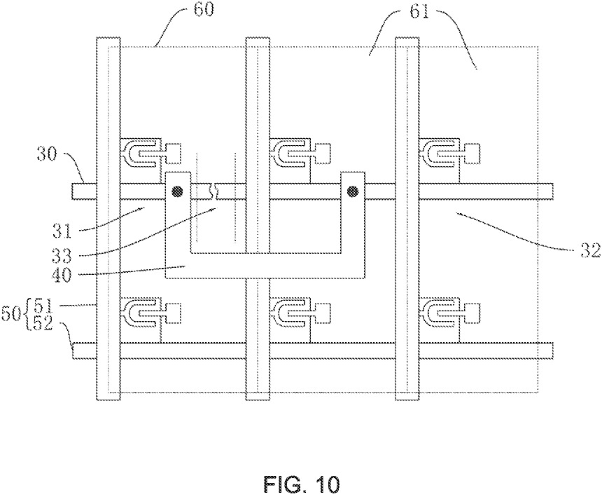

Please refer to FIG. 9 and FIG. 10, the present embodiment provides yet another embodiment, a difference between the first embodiment and the present embodiment is, in the present embodiment, the first signal line 30 is the scan lines 52. The repairing part 40 is disposed in the hollow parts and is disposed on the interlayer insulating layer 22. The interval layer 20 includes the interlayer insulating layer 22 and the gate insulating layer 21. That is, the repairing part 40 is connected to the first signal line 30 by the openings penetrating the interlayer insulating layer 22 and the gate insulating layer 21. Specifically, the repairing part 40 is connected to the first section 31 and the second section 32 of the first signal line 30, respectively, by the openings.

It should be noted that in other embodiments of the present disclosure, the shape of the repairing part may be the straight line or the polyline when the first signal line 30 is the scan line 52, which is not limited here.

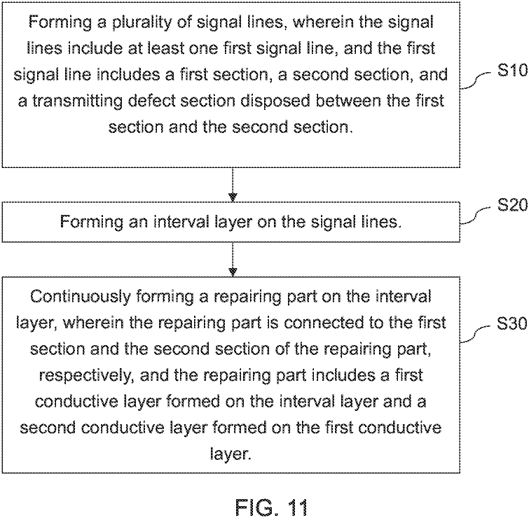

In addition, an embodiment of the present disclosure further provides a method of manufacturing the display panel of the above-mentioned embodiments. Please refer to FIG. 2, FIG. 3, and FIG. 11. Structures as shown in FIG. 2 and FIG. 3 are taken as examples for description. The manufacturing method includes:

S10, forming a plurality of signal lines. The signal lines include at least one first signal line 30. The first signal line 30 includes a first section 31, a second section 32, and a transmitting defect section 33 disposed between the first section 31 and the second section 32.

S20, forming an interval layer 20 on the signal lines.

S30, continuously forming a repairing part 40 on the interval layer 20. The repairing part 40 is connected to the first section 31 and the second section 32 of the repairing part 40, respectively. The repairing part 40 includes a first conductive layer 41 formed on the interval layer 20 and a second conductive layer 42 formed on the first conductive layer 41.

Specifically, the method of manufacturing the display panel provided by the present embodiment includes following steps:

forming a TFT array layer and a color resist layer 60 on a substrate 10, thereby forming an array substrate. The array substrate includes the plurality of signal lines. The signal lines include at least one first signal line 30 and a plurality of second signal lines 50. Wherein, the first signal line 30 includes the first section 31, the second section 32, and the transmitting defect section 33 disposed between the first section 31 and the second section 32. The second signal lines 50 include a plurality of data lines 51 and a plurality of scan lines 52. The first signal line 30 may be the data lines 51 or the scan lines 52. When the first signal line 30 is plural, each of the first signal lines 30 may be individually selected from one of the data lines 51 or the scan lines 52.

Furthermore, the array substrate includes the substrate 10, a gate insulating layer 21 disposed on the substrate 10, an interlayer insulating layer 22 disposed on the gate insulating layer 21, and the color resist layer 60 disposed on the interlayer insulating layer 22. Wherein, the data lines 51 are disposed on the gate insulating layer 21 are covered by the interlayer insulating layer 22. The scan lines 52 are disposed on the substrate 10 and are covered by the gate insulating layer 21. The TFT array layer includes a TFT device. The TFT device includes a gate disposed on a same layer as the scan lines 52 and electrically connected to the scan lines 52, a source and a drain disposed on a same layer as the data lines 51 and electrically connected to the data lines 51, and an active layer, wherein two sides of the active layer are connected to the source and the drain, respectively.

It should be noted that in the structure of the present embodiment as shown in FIG. 2, the interval layer 20 is the interlayer insulating layer 22.

A plurality of hollow parts are formed in the color resist layer 60 corresponding to the first signal line 30. The hollow parts may be formed above the first signal line 30 or may be formed in pixel areas 61 defined on two sides of the first signal line 30. Specifically, the hollow parts are formed by patterning the color resist layer 60 to remove part of color resists of the color resist layer 60. Wherein, the hollow parts overlap part of the first section 31 and second section 32 of the first signal line 30.

The repairing part 40 is disposed in the hollow parts. That is, the repairing part 40 is disposed on the interlayer insulating layer 22.

Specifically, the first conductive layer 41 is disposed in the hollow parts and is disposed on the interlayer insulating layer 22. Furthermore, the first conductive layer 41 overlaps with part of the first section 31 and part of the second section 32. Then, a laser drilling process is performed on an overlapping part between the first conductive layer 41 and the first section 31 and an overlapping part between the conductive layer 41 and the second section 32, thereby forming a plurality of openings. The first conductive layer 41 is connected to the first section 31 and the second section 32, respectively, by the openings.

Optionally, a material of the first conductive layer 41 includes tungsten.

The second conductive layer 42 is disposed on the first conductive layer 41. The second conductive layer 42 overlaps with part of the first section 31 and part of the second section 32, and the openings are on the overlapping parts. Then, a second laser drilling process is performed on the overlapping part between the first conductive layer 41 and the first section 31 and the overlapping part between the first conductive layer 41 and the second section 32, thereby allowing the second conductive layer 42 to connect with the first conductive layer 41 in the openings. That is, the second conductive layer 42 is electrically connected to the first section 31 and the second section 32, respectively.

It should be noted that the openings are formed above the first signal line 30 after the laser drilling process is performed on the first conductive layer 41. However, a size of the openings is relatively small, so that the second conductive layer 42 is difficult to enter the openings. Therefore, in the present embodiment, two laser drilling processes are performed, allowing the second conductive layer 42 to be evenly distributed in the openings. Therefore, the second conductive layer 42 can be connected to the first conductive layer 41 in the openings, thereby improving a repairing effect and increasing a success rate of repairing.

Optionally, a material of the second conductive layer 42 includes silver.

In the present embodiment, the repairing part 40 is formed by stacking the second conductive layer 42 on the first conductive layer 41, and a thickness of the repairing part 40 is equal to a thickness of the color resist layer 60. Therefore, a gap between layers can be further prevented, and a yield rate of products can be improved. Because silver has good fluidity, a repairing defect, such as an uneven thickness or breakage, of the first conductive layer 41 can be further repaired. As such, a success rate of repairing the repairing part 40 is further increased.

An embodiment of the present disclosure further provides a display device, including the display panel of the above-mentioned embodiment. A structure of the display panel is same as the structure of the display panel of the above-mentioned embodiment and is not described again here.

In summary, in the present embodiment, the repairing part 40 having the first conductive layer 41 and the second conductive layer 42 is connected to the first signal line 30. Furthermore, the second conductive layer 42 is disposed on the first conductive layer 41 and overlaps with the first conductive layer 41. The second conductive layer 42 can further repair a repairing defect, such as breakage or an uneven thickness, of the first conductive layer 41, thereby reducing a possibility of breakage occurring on the repairing part 40 and increasing thickness uniformity of the repairing part 40. As such, a success rate of repairing a transmitting defect of the first signal line 30 by the repairing part 40 is effectively increased. Therefore, a yield rate of the display panel is increased, and a display effect is improved.

In the above embodiments, the focus of each embodiment is different, and for a part that is not detailed in an embodiment, reference may be made to related descriptions of other embodiments.

A display panel, a manufacturing method thereof, and a display device have been described in detail by the above embodiments, which illustrate principles and implementations thereof. However, the description of the above embodiments is only for helping to understand the technical solution of the present disclosure and core ideas thereof, and it is understood by those skilled in the art that many changes and modifications to the described embodiment can be carried out without departing from the scope and the spirit of the disclosure that is intended to be limited only by the appended claims.

What is claimed is:

1. A display panel, comprising:
a plurality of signal lines, wherein the signal lines comprise at least one first signal line, the at least one first signal line comprises a first section, a second section, and a transmitting defect section between the first section and the second section;
an interval layer disposed on the at least one first signal line; and
a repairing part continuously disposed on the interval layer and connected to the first section and the second section, respectively, wherein the repairing part comprises a first conductive layer disposed on the interval layer and a second conductive layer disposed on the first conductive layer.

2. The display panel of claim 1, wherein a recess is formed on a side of the first conductive layer toward the second conductive layer, and the second conductive layer is at least filled in the recess.

3. The display panel of claim 1, wherein the second conductive layer is disposed on the interval layer and the first conductive layer, and the second conductive layer covers at least part of the first conductive layer.

4. The display panel of claim 1, wherein fluidity of a material of the second conductive layer is greater than fluidity of a material of the first conductive layer.

5. The display panel of claim 1, wherein a material of the first conductive layer comprises tungsten, and a material of the second conductive layer comprises silver.

6. The display panel of claim 1, further comprising a color resist layer disposed on the interval layer, wherein the color resist layer comprises a plurality of hollow parts, the repairing part is defined in the hollow parts, and two ends of the repairing part are respectively connected to the first section and the second section by a plurality of openings of the interval layer.

7. The display panel of claim 6, wherein the first conductive layer comprises a first connecting section disposed in the openings, the second conductive layer comprises a second connecting section disposed in the openings, and the second connecting section attachedly covers the first connecting section.

8. The display panel of claim 1, wherein a shape of the repairing part comprises a straight line, a polyline, or a curved line.

9. A method of manufacturing a display panel, comprising following steps:
forming a plurality of signal lines, wherein the signal lines comprise at least one first signal line, the first signal line comprises a first section, a second section, and a transmitting defect section between the first section and the second section;
forming an interval layer on the signal lines; and
continuously forming a repairing part on the interval layer, wherein the repairing part is connected to the first section and the second section, respectively, and the repairing part comprises a first conductive layer formed on the interval layer and a second conductive layer formed on the first conductive layer.

10. A display device, comprising a display panel, wherein the display panel comprises:
a plurality of signal lines, wherein the signal lines comprise at least one first signal line, the at least one first signal line comprises a first section, a second section, and a transmitting defect section between the first section and the second section;
an interval layer disposed on the at least one first signal line; and
a repairing part continuously disposed on the interval layer and connected to the first section and the second section, respectively, wherein the repairing part comprises a first conductive layer disposed on the interval layer and a second conductive layer disposed on the first conductive layer.

11. The display device of claim 10, wherein a recess is formed on a side of the first conductive layer toward the second conductive layer, and the second conductive layer is at least filled in the recess.

12. The display device of claim 10, wherein the second conductive layer is disposed on the interval layer and the first conductive layer, and the second conductive layer covers at least part of the first conductive layer.

13. The display device of claim 10, wherein fluidity of a material of the second conductive layer is greater than fluidity of a material of the first conductive layer.

14. The display device of claim 10, wherein a material of the first conductive layer comprises tungsten, and a material of the second conductive layer comprises silver.

15. The display device of claim 10, wherein the display panel further comprises a color resist layer disposed on the interval layer, the color resist layer comprises a plurality of hollow parts, the repairing part is defined in the hollow parts, and two ends of the repairing part are respectively connected to the first section and the second section by a plurality of openings of the interval layer.

16. The display device of claim 15, wherein the first conductive layer comprises a first connecting section disposed in the openings, the second conductive layer comprises a second connecting section disposed in the openings, and the second connecting section attachedly covers the first connecting section.

17. The display device of claim 10, wherein a shape of the repairing part comprises a straight line, a polyline, or a curved line.
